(19) United States
(12) Patent Application Publication
(10) Pub. No.: US 2023/0402289 A1
(43) Pub. Date: Dec. 14, 2023

(54) ETCHING METHOD AND PLASMA PROCESSING SYSTEM

(71) Applicant: Tokyo Electron Limited, Tokyo (JP)

(72) Inventors: Kae TAKAHASHI, Miyagi (JP); Maju TOMURA, Miyagi (JP); Yoshihide KIHARA, Miyagi (JP); Noriyoshi ARIMA, Miyagi (JP)

(73) Assignee: Tokyo Electron Limited, Tokyo (JP)

(21) Appl. No.: 18/207,737

(22) Filed: Jun. 9, 2023

(30) Foreign Application Priority Data
Jun. 10, 2022 (JP) 2022-094167
Apr. 6, 2023 (JP) 2023-061964

(51) Int. Cl. H01L 21/311; H01L 21/3213; H01L 21/033; H01L 21/67; H01L 21/683; H01J 37/32

(52) U.S. Cl. CPC H01L 21/31116; H01L 21/31144; H01L 21/32139; H01L 21/32137; H01L 21/0332; H01L 21/67069; H01L 21/6831; H01J 37/32724; H01J 2237/3341

(57) ABSTRACT

An etching method is implementable with a plasma processing apparatus including a chamber. The method includes (a) providing, in the chamber, a substrate including an etching target film and a mask on the etching target film, and (b) etching the etching target film using plasma generated from a process gas including a hydrogen fluoride gas. The mask contains at least one metal selected from the group consisting of tungsten, molybdenum, ruthenium, titanium, indium, gallium, and zinc.

### CROSS-REFERENCE TO RELATED APPLICATIONS

This application claims priority to Japanese Patent Application No. 2022-094167 filed on Jun. 10, 2022, and Japanese Patent Application No. 2023-061964 filed on Apr. 6, 2023, the entire disclosure of each is incorporated herein by reference.

### BACKGROUND

### Technical Field

Exemplary embodiments of the present disclosure relate to an etching method and a plasma processing system.

### Description of the Background

Patent Literature 1 describes a method for etching a substrate with a polysilicon mask on a silicon-containing film.

### CITATION LIST

### Patent Literature

Patent Literature 1: Japanese Unexamined Patent Application Publication No. 2016-21546

### BRIEF SUMMARY

One or more aspects of the present disclosure are directed to a technique for improving etch selectivity.

An etching method according to one exemplary embodiment of the present disclosure is implementable with a plasma processing apparatus including a chamber. The method includes (a) providing, in the chamber, a substrate including an etching target film and a mask on the etching target film, and (b) etching the etching target film using plasma generated from a process gas including a hydrogen fluoride gas. The mask contains at least one metal selected from the group consisting of tungsten, molybdenum, ruthenium, titanium, indium, gallium, and zinc.

The technique according to one exemplary embodiment of the present disclosure improves etch selectivity.

### BRIEF DESCRIPTION OF DRAWINGS

FIG. 1 is a schematic diagram of an exemplary plasma processing system.

FIG. 2 is a flowchart of an exemplary processing method according to an embodiment.

FIG. 3 is a diagram of a substrate W showing an example cross-sectional structure.

FIG. 4 is a diagram of the substrate W showing an example cross-sectional structure at the end of step ST12.

FIG. 5 is a flowchart of an exemplary processing method according to another embodiment.

FIG. 6 is a diagram of a substrate W1 showing an example cross-sectional structure.

FIG. 7 is a graph showing the results of Experiment 1.

FIG. 8 is a plan view of masks MK after etching, showing their features.

### DETAILED DESCRIPTION

One or more embodiments of the present disclosure will be described below.

An etching method according to one exemplary embodiment of the present disclosure is implementable with a plasma processing apparatus including a chamber. The method includes (a) providing, in the chamber, a substrate including an etching target film and a mask on the etching target film, and (b) etching the etching target film using plasma generated from a process gas including a hydrogen fluoride gas. The mask contains at least one metal selected from the group consisting of tungsten, molybdenum, ruthenium, titanium, indium, gallium, and zinc.

In one exemplary embodiment, the mask contains a carbide or a silicide of the at least one metal.

In one exemplary embodiment, the mask contains at least one selected from the group consisting of Ru, WSi, TiN, Mo, and InGaZnO.

In one exemplary embodiment, the mask further contains at least one selected from the group consisting of silicon, carbon, and nitrogen.

In one exemplary embodiment, the process gas further includes a phosphorus-containing gas.

In one exemplary embodiment, the phosphorus-containing gas includes a phosphorus halide gas.

In one exemplary embodiment, the phosphorus-containing gas contains at least one of fluorine or chlorine.

In one exemplary embodiment, the process gas includes the hydrogen fluoride gas with a highest flow rate of non-inert components of the process gas.

In one exemplary embodiment, the process gas further includes at least one gas selected from the group consisting of a tungsten-containing gas, a titanium-containing gas, and a molybdenum-containing gas.

In one exemplary embodiment, (b) includes setting a temperature of a substrate support supporting the substrate to 0° C. or lower.

In one exemplary embodiment, the etching target film includes at least one selected from the group consisting of a silicon oxide film, a silicon nitride film, a polysilicon film, and a film stack including at least two of the silicon oxide film, the silicon nitride film, or the polysilicon film.

In one exemplary embodiment, the etching target film is a silicon-containing film, a carbon-containing film, or a metal oxide film.

In one exemplary embodiment, the etching target film is a film stack including a silicon oxide film and a silicon nitride film, and (b) includes (b1) etching the silicon oxide film and (b2) etching the silicon nitride film, and (b) includes controlling a temperature of the substrate to be higher in (b2) than in (b1).

In one exemplary embodiment, the controlling the temperature includes at least one selected from the group consisting of (I) controlling a duty ratio of a source radio frequency signal to be provided to the chamber to be greater in (b2) than in (b1), (II) controlling a duty ratio of a bias signal to be provided to a substrate support supporting the substrate to be greater in (b2) than in (b1), (III) controlling a pressure of a heat-transfer gas to be supplied between the substrate and the substrate support to be lower in (b2) than in (b1), (IV) controlling a voltage to be provided to an electrostatic chuck in the substrate support to be lower in (b2) than in (b1), and (V) controlling a temperature of a heat-transfer fluid to be supplied to a channel in the substrate support to be higher in (b2) than in (b1).

In one exemplary embodiment, the heat-transfer fluid has a same temperature in (b1) and (b2), and the controlling the temperature includes at least one selected from the group consisting of (I) to (IV).

An etching method in one exemplary embodiment is implementable with a plasma processing apparatus including a chamber. The method includes (a) providing, in the chamber, a substrate including an etching target film and a mask on the etching target film, and (b) etching the etching target film using plasma including a hydrogen fluoride species. The mask contains at least one selected from the group consisting of tungsten, molybdenum, ruthenium, titanium, indium, gallium, and zinc.

In one exemplary embodiment, the hydrogen fluoride species is generated from at least one of a hydrogen fluoride gas or a hydrofluorocarbon gas.

In one exemplary embodiment, the hydrogen fluoride species is generated from a hydrofluorocarbon gas having at least two carbon atoms.

In one exemplary embodiment, the hydrogen fluoride species is generated from a mixture gas including a hydrogen source and a fluorine source.

A plasma processing system in one exemplary embodiment includes a plasma processing apparatus including a chamber, and a controller. The controller performs control to cause operations including (a) providing, in the chamber, a substrate including an etching target film and a mask on the etching target film, and (b) etching the etching target film using plasma generated from a process gas including a hydrogen fluoride gas. The mask contains at least one metal selected from the group consisting of tungsten, molybdenum, ruthenium, titanium, indium, gallium, and zinc.

One or more embodiments of the present disclosure will now be described with reference to the drawings. In the drawings, the same or similar components are given the same reference numerals and may not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example Structure of Plasma Processing System

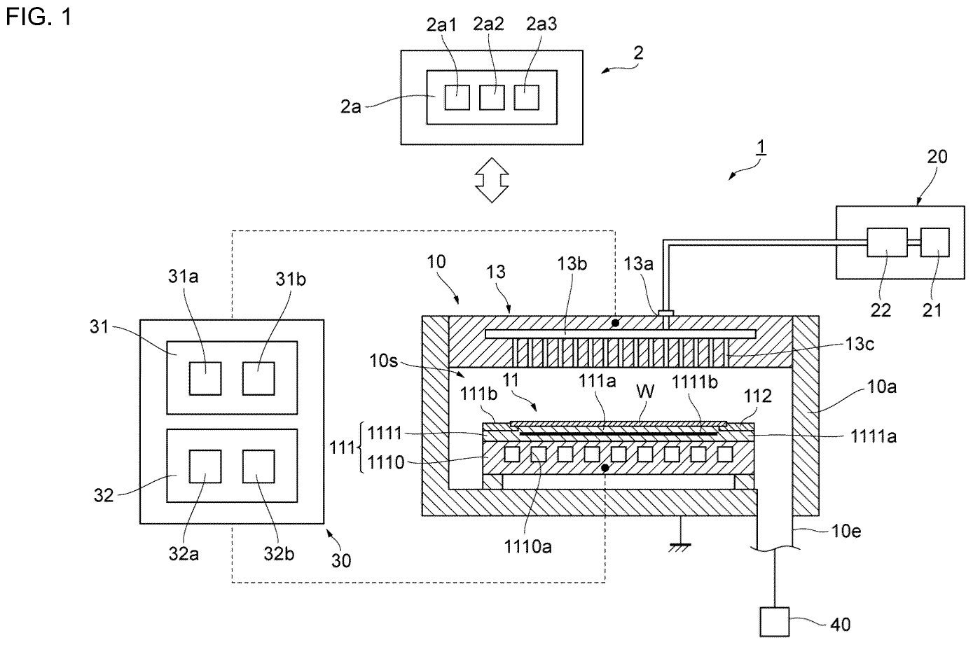

An example structure of a plasma processing system will now be described. FIG. 1 is a diagram of a capacitively coupled plasma processing apparatus showing its example structure.

The plasma processing system includes a capacitively coupled plasma processing apparatus 1 and a controller 2. The capacitively coupled plasma processing apparatus 1 includes a plasma processing chamber 10, a gas supply unit 20, a power supply 30, and an exhaust system 40. The plasma processing apparatus 1 also includes a substrate support 11 and a gas inlet unit. The gas inlet unit allows at least one process gas to be introduced into the plasma processing chamber 10. The gas inlet unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas inlet for supplying at least one process gas into the plasma processing space 10s and at least one gas outlet for discharging the gas from the plasma processing space 10s. The plasma processing chamber 10 is grounded. The shower head 13 and the substrate support 11 are electrically insulated from a housing of the plasma processing chamber 10.

The substrate support 11 includes a body 111 and a ring assembly 112. The body 111 includes a central area 111a for supporting a substrate W and an annular area 111b for supporting the ring assembly 112. A wafer is an example of the substrate W. The annular area 111b of the body 111 surrounds the central area 111a of the body 111 as viewed in plan. The substrate W is located on the central area 111a of the body 111. The ring assembly 112 is located on the annular area 111b of the body 111 to surround the substrate W on the central area 111a of the body 111. Thus, the central area 111a is also referred to as a substrate support surface for supporting the substrate W, and the annular area 11b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may serve as a lower electrode. The ESC 1111 is located on the base 1110. The ESC 1111 includes a ceramic member 1111a and an electrostatic electrode 1111b located inside the ceramic member 1111a. The ceramic member 1111a includes the central area 111a. In one embodiment, the ceramic member 1111a also includes the annular area 111b. Other members surrounding the ESC 1111, such as an annular ESC or an annular insulating member, may include the annular area 111b. In this case, the ring assembly 112 may be located on the annular ESC or the annular insulating member, or may be located on both the ESC 1111 and the annular insulating member. At least one radio frequency (RF) electrode coupled to an RF power supply 31 or at least one direct current (DC) electrode coupled to a DC power supply 32 may also be located inside the ceramic member 1111a, or both the RF electrode and the DC electrode (described later) may also be located inside the ceramic member 1111a. In this case, at least one RF electrode or at least one DC electrode serves as a lower electrode, or both the electrodes serve as lower electrodes. When a bias RF signal, a DC signal, or both the signals (described later) are provided to at least one RF electrode, to at least one DC electrode, or to both the electrodes, the RF electrode, the DC electrode, or both the electrodes are also referred to as a bias electrode(s). The conductive member in the base 1110 and at least one RF electrode, at least one DC electrode, or both the electrodes may serve as multiple lower electrodes. The electrostatic electrode 1111b may also serve as a lower electrode. Thus, the substrate support 11 includes at least one lower electrode.

The ring assembly 112 includes one or more annular members. In one embodiment, one or more annular members include one or more edge rings and at least one cover ring. The edge ring is formed from a conductive material or an insulating material. The cover ring is formed from an insulating material.

The substrate support 11 may also include a temperature control module that adjusts at least one of the ESC 1111, the ring assembly 112, or the substrate to a target temperature. The temperature control module may include a heater, a heat-transfer medium, a channel 1110a, or a combination of these. The channel 1110a allows a heat-transfer fluid such as brine or gas to flow. In one embodiment, the channel 1110a is defined in the base 1110, and one or more heaters are located in the ceramic member 1111a in the ESC 1111. The substrate support 11 may include a heat-transfer gas supply unit to supply a heat-transfer gas into a space between the back surface of the substrate W and the central area 111a.

The shower head 13 introduces at least one process gas from the gas supply unit 20 into the plasma processing space 10s. The shower head 13 has at least one gas inlet 13a, at least one gas-diffusion compartment 13b, and multiple gas inlet ports 13c. The process gas supplied to the gas inlet 13a passes through the gas-diffusion compartment 13b and is introduced into the plasma processing space 10s through the multiple gas inlet ports 13c. The shower head 13 also includes at least one upper electrode. In addition to the shower head 13, the gas inlet unit may include one or more side gas injectors (SGIs) that are installed in one or more openings in the side wall 10a.

The gas supply unit 20 may include at least one gas source 21 and at least one flow controller 22. In one embodiment, the gas supply unit 20 allows supply of at least one process gas from each gas source 21 to the shower head 13 through the corresponding flow controller 22. The flow controller 22 may include a mass flow controller or a pressure-based flow controller. The gas supply unit 20 may further include one or more flow rate modulators that supply at least one gas at a modulated flow rate or in a pulsed manner.

The power supply 30 includes the RF power supply 31 that is coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s. The RF power supply 31 may thus at least partially serve as a plasma generator that generates plasma from one or more process gases in the plasma processing chamber 10. A bias RF signal is provided to at least one lower electrode to generate a bias potential in the substrate W, thus drawing ion components in the plasma to the substrate W.

In one embodiment, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated one or more source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, at least one of the first DC signal or the second DC signal may be pulsed. In this case, a sequence of voltage pulses is applied to at least one lower electrode, to at least one upper electrode, or to both the electrodes. The voltage pulse may have a rectangular, trapezoidal, or triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator are included in a voltage pulse generator. When the second DC generator 32b and the waveform generator are included in a voltage pulse generator, the voltage pulse generator is coupled to at least one upper electrode. The voltage pulses may have positive or negative polarity. The sequence of voltage pulses may also include one or more positive voltage pulses and one or more negative voltage pulses within one cycle. The first DC generator 32a and the second DC generator 32b may be provided in addition to the RF power supply 31, or the first DC generator 32a may replace the second RF generator 31b.

The exhaust system 40 may be, for example, connected to a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

The controller 2 processes computer-executable instructions that cause the plasma processing apparatus 1 to perform various steps described in one or more embodiments of the present disclosure. The controller 2 may control the components of the plasma processing apparatus 1 to perform various steps described herein. In one embodiment, some or all of the components of the controller 2 may be included in the plasma processing apparatus 1. The controller 2 may include a processor 2al, a storage 2a2, and a communication interface 2a3. The controller 2 is implemented by, for example, a computer 2a. The processor 2al may perform various control operations by reading a program from the storage 2a2 and executing the read program. This program may be prestored in the storage 2a2 or may be obtained through a medium as appropriate. The obtained program is stored into the storage 2a2, read from the storage 2a2, and executed by the processor 2a1. The medium may be one of various storage media readable by the computer 2a, or a communication line connected to the communication interface 2a3. The processor 2al may be a central processing unit (CPU). The storage 2a2 may be a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

### Exemplary Plasma Processing Method

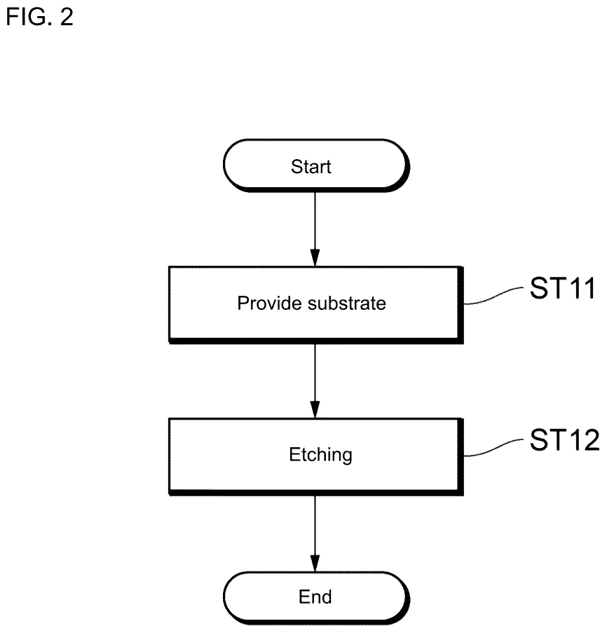

FIG. 2 is a flowchart of a plasma processing method according to an exemplary embodiment (hereinafter also referred to as the processing method) according to an exemplary embodiment. As shown in FIG. 2, the processing method includes step ST11 in which a substrate is provided and step ST12 in which etching is performed. The processing in each step may be performed in the plasma processing system shown in FIG. 1. The controller 2 controls the components of the plasma processing apparatus 1 to perform the processing method on a substrate W.

### Step ST11: Providing Substrate

In step ST11, the substrate W is provided in the plasma processing space 10s in the plasma processing apparatus 1. The substrate W is placed on the central area 11a included in the substrate support 11. The substrate W is held on the substrate support 11 by the ESC 1111.

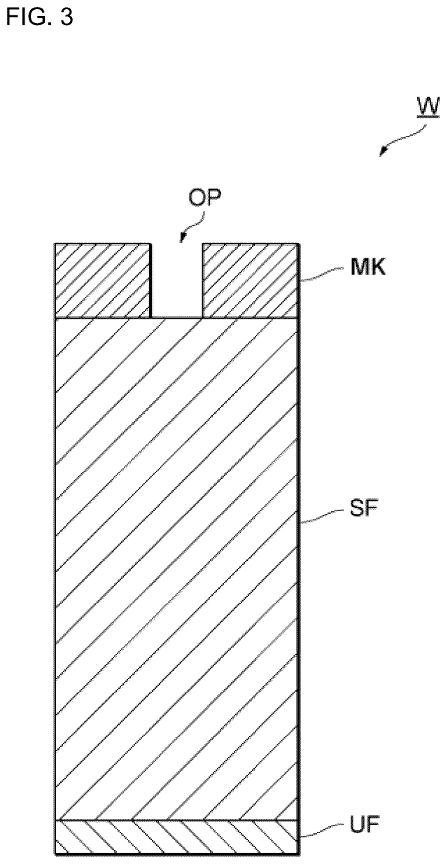

FIG. 3 is a diagram of the substrate W provided in step ST11, showing an example cross-sectional structure. The substrate W includes a silicon-containing film SF as an etching target film and a mask MK on the silicon-containing film SF. The silicon-containing film SF may be located on an underlying film UF. The substrate W may be used for manufacturing semiconductor devices. Examples of the semiconductor devices include semiconductor memory devices such as a dynamic RAM (DRAM) and a 3D-NAND flash memory.

The underlying film UF may be, for example, a silicon wafer or an organic film, a dielectric film, a metal film, or a semiconductor film on the silicon wafer. In one embodiment, the underlying film UF may be an etch stop film. In one embodiment, the etch stop film contains at least one metal selected from the group consisting of tungsten, molybdenum, ruthenium, titanium, indium, gallium, and zinc. The etch stop film may contain, for example, a carbide or a silicide of tungsten, molybdenum, or titanium. The etch stop film may be, for example, a tungsten-containing film. The etch stop film may further contain tungsten and at least one selected from the group consisting of silicon, carbon, and nitrogen. In one example, the etch stop film contains at least one selected from the group consisting of tungsten carbide (WC), tungsten silicide (WSi), tungsten silicon nitride (WSiN), and tungsten silicon carbide (WSiC). The etch stop film may contain, for example, at least one selected from the group consisting of Ru, WSi, TiN, Mo, and InGaZnO. The underlying film UF may include multiple films stacked on one another. For the underlying film UF including multiple films, the etch stop film may be formed on the uppermost layer of the underlying film UF. In other words, the silicon-containing film SF may be in contact with the etch stop film.

The silicon-containing film SF is a target film of etching with the processing method. Examples of the silicon-containing film SF include a silicon oxide film, a silicon nitride film, a silicon oxynitride film, a silicon carbonitride film, a polycrystalline silicon film, and a carbon-containing silicon film. The silicon-containing film SF may include multiple films stacked on one another. For example, the silicon-containing film SF may include silicon oxide films and silicon nitride films alternately stacked on one another. For example, the silicon-containing film SF may include silicon oxide films and polycrystalline silicon films ultimately stacked on one another. For example, the silicon-containing film SF may be a film stack including a silicon nitride film, a silicon oxide film, and a polycrystalline silicon film. For example, the silicon-containing film SF may include a silicon oxide film and a silicon carbonitride film stacked on each other. For example, the silicon-containing film SF may be a film stack including a silicon oxide film, a silicon nitride film, and a silicon carbonitride film. In one embodiment, the substrate W may include a carbon-containing film or a metal oxide film in place of the silicon-containing film SF. In this case, the carbon-containing film or the metal oxide film is a target film of etching with the processing method. The etching target film may contain impurities such as boron, nitrogen, and phosphorus.

The mask MK contains at least one metal selected from the group consisting of tungsten, molybdenum, ruthenium, titanium, indium, gallium, and zinc. The mask MK may contain, for example, a carbide or a silicide of tungsten, molybdenum, or titanium. The mask MK may be, for example, a tungsten-containing film. The mask MK may further contain tungsten and at least one selected from the group consisting of silicon, carbon, and nitrogen. In one example, the mask MK contains at least one selected from the group consisting of WC, WSi, WSiN, and WSiC. The mask MK may contain, for example, at least one selected from the group consisting of Ru, WSi, TiN, Mo, and InGaZnO. The mask MK may be a single layer mask including one layer or a multilayer mask including two or more layers.

As shown in FIG. 3, the mask MK may define at least one opening OP on the silicon-containing film SF. The opening OP is a space on the silicon-containing film SF, surrounded by a side wall of the mask MK. In other words, the upper surface of the silicon-containing film SF includes a portion covered with the mask MK and a portion exposed through the bottom of the opening OP.

The opening OP may have any feature in a plan view of the substrate W, or in other words, when the substrate W is viewed from the top toward the bottom in FIG. 3. The opening feature may be, for example, a circle, an oval, a rectangle, a line, or a combination of one or more of these features. The mask MK may have multiple side walls, which may define multiple openings OP. The multiple openings OP may be slits arranged in a pattern of lines and spaces at regular intervals. The multiple openings OP may be holes in a patterned array.

The films (the underlying film UF, the silicon-containing film SF, and the mask MK) included in the substrate W may each be formed by chemical vapor deposition (CVD), atomic layer deposition (ALD), spin coating, or other methods. The mask MK may be formed by lithography. The opening OP in the mask MK may be formed by etching the mask MK. The films may each be a flat film or an uneven film. The substrate W may include another film under the underlying film UF. In this structure, the silicon-containing film SF and the underlying film UF may have recesses with features corresponding to the opening OP, and the other film may be used as a mask for etching.

The processing for forming each film included in the substrate W may be at least partly performed in a space in the plasma processing chamber 10. In one example, the step of etching the mask MK to form the opening OP may be performed in the plasma processing chamber 10. In other words, the etching of the opening OP and the etching of the silicon-containing film SF (described later) may be performed continuously in the same chamber. All or some of the films included in the substrate W may be formed in a device or a chamber external to the plasma processing apparatus 1. The resultant substrate W may then be loaded into the plasma processing space 10s in the plasma processing apparatus 1 and placed on the central area 111a of the substrate support 11.

After the substrate W is placed on the central area 111a of the substrate support 11, the temperature of the substrate support 11 is adjusted to a set temperature by the temperature control module. The set temperature may be, for example, lower than or equal to 0, −10, −20, −30, −40, −50, −60, or −70° C. In one example, adjusting or maintaining the temperature of the substrate support 11 includes causing the temperatures of the heat-transfer fluid flowing in the channel 1110a and the heater to be set temperatures, or to be temperatures different from the set temperatures. The heat-transfer fluid may start to flow in the channel 1110a before, after, or at the same time as the substrate W is placed on the substrate support 11. The temperature of the substrate support 11 may be adjusted to the set temperature before step ST11. In other words, the substrate W may be placed on the substrate support 11 after the temperature of the substrate support 11 is adjusted to the set temperature.

### Step ST12: Etching

In step ST12, plasma generated from a process gas is used for etching the silicon-containing film SF. The gas supply unit 20 supplies the process gas into the plasma processing space 10s. During the processing in step ST12, gases included in the process gas and the flow rate (partial pressure) of each gas may or may not be changed. For a silicon-containing film SF being a film stack including different types of silicon-containing films, for example, the composition of the process gases or the flow rate (partial pressure) of each gas may be changed as the etching proceeds or depending on the type of film to be etched. During the processing in step ST12, the substrate support 11 may be maintained at the set temperature reached by the adjustment in step ST11, or may be changed as the etching proceeds or depending on the type of film to be etched.

A source RF signal is then provided to the lower electrode of the substrate support 11, to the upper electrode of the shower head 13, or to both the electrodes. This causes generation of an RF electric field between the shower head 13 and the substrate support 11, and generation of first plasma from the process gas in the plasma processing space 10s. A bias signal is also provided to the lower electrode of the substrate support 11 to generate a bias potential between the plasma and the substrate W. The bias potential attracts an active species such as ions and radicals in the plasma to the substrate W. The silicon-containing film SF is thus etched in a portion uncovered with the mask MK (a portion exposed in the opening OP).

In step ST12, the bias signal may be a bias RF signal provided from the second RF generator 31b. The bias signal may be a bias DC signal provided from the first DC generator 32a. The source RF signal and the bias signal may both be continuous waves or pulsed waves, or one signal may be continuous and the other signal may be pulsed. When both the source RF signal and the bias signal are pulsed, the cycles of the two pulsed waves may or may not be synchronized. The pulsed source RF signal, the pulsed bias signal, or both the pulsed signals may have a duty ratio set as appropriate to, for example, 1 to 80% or 5 to 50%. The duty ratio is the percentage of the period in which the level of power or the level of voltage is higher in a pulse wave cycle. A bias DC signal used as the bias signal may have a rectangular, trapezoidal, or triangular pulse waveform, or a combination of these pulse waveforms. The bias DC signal may have either negative or positive polarity, and may adjust the potential of the substrate W to create a potential difference between the plasma and the substrate W to draw ions.

In step ST12, an HF gas included in the process gas may have the highest flow rate (partial pressure) of all components of the process gas (all components of the process gas excluding any inert components included in the gas). In one example, the HF gas may have a flow rate of at least 50, 60, 70, 80, 90, or 95 vol % of the total flow rate of all components of the process gas (all components of the process gas excluding any inert components included in the gas; the same applies hereinafter). The flow rate of the HF gas may be less than 100 vol %, or 99.5, 98, or 96 vol % or less of the total flow rate of all components of the process gas. In one example, the HF gas is controlled to have a flow rate of 70 to 96 vol % inclusive of the total flow rate of all components of the process gas.

The process gas may further include a phosphorus-containing gas. The phosphorus-containing gas has a phosphorus-containing molecule. The phosphorus-containing molecule may be an oxide such as tetraphosphorus decaoxide (P₄O₁₀), tetraphosphorus octoxide (P₄O₈), or tetraphosphorus hexaoxide (P₄O₆). Tetraphosphorus decaoxide may also be referred to as diphosphorus pentaoxide (P₂O₅). The phosphorus-containing molecule may be a halide (phosphorus halide) such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), or phosphorus iodide (PI₃). More specifically, the halogen contained in the phosphorus-containing molecule may be fluorine in, for example, a phosphorus fluoride. In some embodiments, the phosphorus-containing molecule may contain a non-fluorine halogen. The phosphorus-containing molecule may be a phosphoryl halide such as phosphoryl fluoride (POF₃), phosphoryl chloride (POCl₃), or phosphoryl bromide (POBr₃). The phosphorus-containing molecule may be phosphine (PH₃), calcium phosphide (e.g., Ca₃P₂), phosphoric acid (H₃PO₄), sodium phosphate (Na₃PO₄), or hexafluorophosphoric acid (HPF₆). The phosphorus-containing molecule may be a fluorophosphine (H_{g}PFₕ), where the sum of g and h is 3 or 5. The fluorophosphine may be, for example, HPF₂ or H₂PF₃. The process gas may have at least one phosphorus-containing molecule selected from the above phosphorus-containing molecules. For example, the process gas may contain at least one phosphorus-containing molecule selected from the group consisting of PF₃, PCl₃, PF₅, PCl₅, POCl₃, PH₃, PBr₃, and PBr₅. Each phosphorus-containing molecule in the process gas in either liquid or solid form may be vaporized by, for example, heating before being supplied into the plasma processing space 10s.

The phosphorus-containing gas may be a PClₐF_{b} gas (where a is an integer greater than or equal to 1, b is an integer greater than or equal to 0, and the sum of a and b is an integer less than or equal to 5) or a PC_{c}H_{d}Fₑ gas (where d and e are integers of 1 to 5 inclusive, and c is an integer of 0 to 9 inclusive).

The PClₐF_{b} gas may be, for example, at least one gas selected from the group consisting of a PClF₂ gas, a PCl₂F gas, and a PCl₂F₃ gas.

The PC_{c}H_{d}Fₑ gas may be, for example, at least one gas selected from the group consisting of a PF₂CH₃ gas, a PF(CH₃)₂ gas, a PH₂CF₃ gas, a PH(CF₃)₂ gas, a PCH₃(CF₃)₂ gas, a PH₂F gas, and a PF₃(CH₃)₂ gas.

The phosphorus-containing gas may be a PCl_{c}F_{d}CₑH_{f} gas (where c, d, e, and f are integers greater than or equal to 1). The phosphorus-containing gas may be a gas containing P (phosphorus), F (fluorine), and a halogen other than F (e.g., Cl, Br, or I) in its molecular structure, a gas containing P, F, C (carbon), and H (hydrogen) in its molecular structure, or a gas containing P, F, and H in its molecular structure.

The phosphorus-containing gas may be a phosphine gas. Examples of the phosphine gas include phosphine (PH₃), compounds in which at least one hydrogen atom of phosphine is substituted with an appropriate substituent, and phosphinic acid derivatives.

Hydrogen atoms of phosphine may be substituted with any substituents. Example substituents include halogen atoms such as a fluorine atom and a chlorine atom, alkyl groups such as a methyl group, an ethyl group, and a propyl group, and hydroxyalkyl groups such as a hydroxymethyl group, a hydroxyethyl group, and a hydroxypropyl group. One example may be a chlorine atom, a methyl group, or a hydroxymethyl group.

Examples of the phosphinic acid derivatives include phosphinic acid (H₃O₂P), alkyl phosphinic acid (PHO(OH)R), and dialkyl phosphinic acid (PO(OH)R₂).

The phosphine gas may include, for example, at least one gas selected from the group consisting of a PCH₃Cl₂ (dichloro(methyl)phosphine) gas, a P(CH₃)₂Cl (chloro(dimethyl)phosphine) gas, a P(HOCH₂)Cl₂ (dichloro(hydroxymethyl)phosphine) gas, a P(HOCH₂)₂Cl (chloro(dihydroxylmethyl)phosphine) gas, a P(HOCH₂)(CH₃)₂ (dimethyl(hydroxylmethyl)phosphine) gas, a P(HOCH₂)₂(CH₃)₂ (methyl(dihydroxylmethyl)phosphine) gas, a P(HOCH₂)₃(tris(hydroxylmethyl)phosphine) gas, an H₃O₂P (phosphinic acid) gas, a PHO(OH)(CH₃) (methyl phosphinic acid) gas, and a PO(OH)(CH₃)₂ (dimethyl phosphinic acid) gas.

The flow rate of the phosphorus-containing gas included in the process gas may be 20, 10, or 5 vol % or less of a total flow rate of all components of the process gas.

The process gas may further include a tungsten-containing gas. The tungsten-containing gas may be a gas containing tungsten and a halogen, or for example, a WFₓCl_{y} gas (where x and y are integers of 0 to 6 inclusive, and the sum of x and y is an integer of 2 to 6 inclusive). More specifically, the tungsten-containing gas may be a gas containing tungsten and fluorine, such as a tungsten difluoride (WF₂) gas, a tungsten tetrafluoride (WF₄) gas, a tungsten pentafluoride (WF₅) gas, and a tungsten hexafluoride (WF₆) gas, or a gas containing tungsten and chlorine, such as a tungsten dichloride (WCl₂) gas, a tungsten tetrachloride (WCl₄) gas, a tungsten pentachloride (WCl₅) gas, and a tungsten hexachloride (WCl₆) gas. Of these gases, the tungsten-containing gas may be at least one of a WF₆ gas or a WCl₆ gas. The flow rate of the tungsten-containing gas may be 5 vol % or less of the total flow rate of all components of the process gas. The process gas may include at least one of a titanium-containing gas or a molybdenum-containing gas in place of or in addition to a tungsten-containing gas.

The process gas may further include a carbon-containing gas. The carbon-containing gas may be, for example, either or both of a fluorocarbon gas and a hydrofluorocarbon gas. In one example, the fluorocarbon gas may be at least one selected from the group consisting of a CF₄ gas, a C₂F₂ gas, a C₂F₄ gas, a C₃F₆ gas, a C₃F₈ gas, a C₄F₆ gas, a C₄F₈ gas, and a C₅F₈ gas. In one example, the hydrofluorocarbon gas may be at least one selected from the group consisting of a CHF₃ gas, a CH₂F₂ gas, a CH₃F gas, a C₂HF₅ gas, a C₂H₂F₄ gas, a C₂H₃F₃ gas, a C₂H₄F₂ gas, a C₃HF₇ gas, a C₃H₂F₂ gas, a C₃H₂F₄ gas, a C₃H₂F₆ gas, a C₃H₃F₅ gas, a C₄H₂F₆ gas, a C₄H₅F₅ gas, a C₄H₂F₈ gas, a C₅H₂F₆ gas, a C₅H₂F₁₀ gas, and a C₅H₃F₇ gas. The carbon-containing gas may have a linear chain structure with unsaturated bonds. The linear carbon-containing gas with unsaturated bonds may be, for example, at least one selected from the group consisting of a C₃F₆(hexafluoropropene) gas, a C₄F₈ (octafluoro-1-butene, octafluoro-2-butene) gas, a C₃H₂F₄ (1,3,3,3-tetrafluoropropene) gas, a C₄H₂F₆ (trans-1,1,1,4,4,4-hexafluoro-2-butene) gas, a C₄F₈O (pentafluoroethyl trifluorovinyl ether) gas, a CF₃COF gas (1,2,2,2-tetrafluoroethane-1-one), a CHF₂COF (difluoroacetic acid fluoride) gas, and a COF₂ (carbonyl fluoride) gas.

The process gas may further include an oxygen-containing gas. The oxygen-containing gas may be, for example, at least one gas selected from the group consisting of O₂, CO, CO₂, H₂O, and H₂O₂. In one example, the oxygen-containing gas may be at least one gas selected from the group consisting of oxygen-containing gases other than H₂O, or specifically, O₂, CO, CO₂, and H₂O₂. The flow rate of the oxygen-containing gas may be adjusted in accordance with the flow rate of the carbon-containing gas. The oxygen-containing gas functions as a declogging gas as described later, and may have the effect of promoting etching of silicon-containing film, particularly silicon oxide film. The oxygen-containing gas promotes the adsorption of etchant (hydrogen fluoride species) onto the silicon-containing film.

The process gas may further include a halogen-containing gas other than fluorine. The halogen-containing gas other than fluorine may be at least one of a chlorine-containing gas, a bromine-containing gas, or an iodine-containing gas. In one example, the chlorine-containing gas may be at least one gas selected from the group consisting of Cl₂, SiCl₂, SiCl₄, CCl₄, SiH₂Cl₂, Si₂Cl₆, CHCl₃, SO₂Cl₂, BCl₃, PCl₃, PCl₅, and POCl₃. In one example, the bromine-containing gas may be at least one gas selected from the group consisting of Br₂, HBr, CBr₂F₂, C₂F₅Br, PBr₃, PBr₅. POBr₃, and BBr₃. In one example, the iodine-containing gas may be at least one gas selected from the group consisting of HI, CF₃I, C₂F₅I, C₃F₇I, IF₅, IF₇, I₂, and PI₃. In one example, the halogen-containing gas other than fluorine may be at least one selected from the group consisting of a Cl₂ gas, a Br₂ gas, and an HBr gas. In one example, the halogen-containing gas other than fluorine is a Cl₂ gas or an HBr gas.

The process gas may further include an inert gas. In one example, the inert gas may be a noble gas such as an Ar gas, a He gas, and a Kr gas, or a nitrogen gas.

The process gas may include, in place of part or all of the HF gas, a gas for generating an HF species in plasma. The HF species includes at least any of an HF gas, radicals, or ions.

The gas for generating an HF species may be, for example, a hydrofluorocarbon gas. The hydrofluorocarbon gas may have at least two, three, or four carbon atoms. In one example, the hydrofluorocarbon gas is at least one selected from the group consisting of a CH₂F₂ gas, a C₃H₂F₄ gas, a C₃H₂F₆ gas, a C₃H₃F₅ gas, a C₄H₂F₆ gas, a C₄H₅F₅ gas, a C₄H₂F₈ gas, a C₅H₂F₆ gas, a C₅H₂F₈ gas, and a C₅H₃F₇ gas. In one example, the hydrofluorocarbon gas is at least one selected from the group consisting of a CH₂F₂ gas, a C₃H₂F₄ gas, a C₃H₂F₆ gas, and a C₄H₂F₆ gas.

The gas for generating an HF species may be, for example, a mixture gas including a hydrogen source and a fluorine source. The hydrogen source may be, for example, at least one selected from the group consisting of an H₂ gas, an NH₃ gas, an H₂O gas, an H₂O₂ gas, and a hydrocarbon gas (e.g., a CH₄ gas or a C₃H₆ gas). The fluorine source may be, for example, a carbon-free fluorine-containing gas, such as an NF₃ gas, an SF₆ gas, a WF₆ gas, or an XeF₂ gas. The fluorine source may be a carbon-containing fluorine-containing gas, such as a fluorocarbon gas or a hydrofluorocarbon gas. In one example, the fluorocarbon gas may be at least one selected from the group consisting of a CF₄ gas, a C₂F₂ gas, a C₂F₄ gas, a C₃F₆ gas, a C₃F₈ gas, a C₄F₆ gas, a C₄F₈ gas, and a CSFs gas. In one example, the hydrofluorocarbon gas is at least one selected from the group consisting of a CHF₃ gas, a CH₂F₂ gas, a CH₃F gas, a C₂HF₅ gas, and a hydrofluorocarbon gas having at least three carbon atoms (e.g., a C₃H₂F₄ gas, a C₃H₂F₆ gas, or a C₄H₂F₆ gas).

The silicon-containing film SF is etched to form a recess based on the feature of the opening OP in the mask MK in step ST12. When a predetermined stop condition is satisfied, the etching in step ST12 is stopped to end the processing performed with the method. The stop condition may be set based on, for example, the etching time or the depth of the recess.

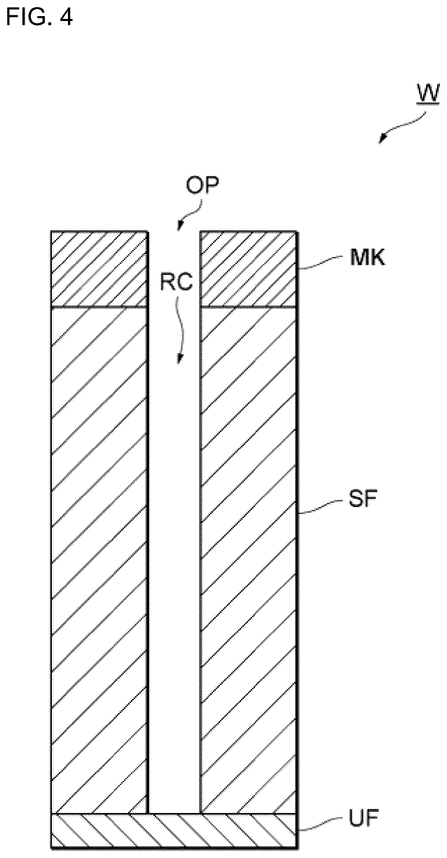

FIG. 4 is a diagram of the substrate W showing an example cross-sectional structure at the end of step ST12. As shown in FIG. 4, in the processing in step ST12, the portion of the silicon-containing film SF exposed through the opening OP is etched in the depth direction (from the top to the bottom in FIG. 4) to form a recess RC. In the example shown in FIG. 4, the recess RC is etched to have its bottom reaching the underlying film UF in step ST12, exposing the underlying film UF. The recess RC in this state may have an aspect ratio of, for example, 20 or more, or 30, 40, 50, or 100 or more.

With the processing method, the mask MK in the substrate W contains at least one metal selected from the group consisting of tungsten, molybdenum, ruthenium, titanium, indium, gallium, and zinc. These metals have higher etching resistance to plasma including an HF species generated during etching in step ST12. Thus, the silicon-containing film SF can be etched with plasma including an HF species in step ST12 with the mask MK being less likely to be etched. This improves selectivity in etching of the silicon-containing film SF to the mask MK. The same applies to a substrate W including a carbon-containing film or a metal oxide film in place of the silicon-containing film SF (an etching target film being a carbon-containing film or a metal oxide film). The processing method thus improves the selectivity in etching of the silicon-containing film to the mask MK. With a substrate W including an etch stop film containing any of the above metals as the underlying film UF, the underlying film UF in step ST12 is less likely to be etched.

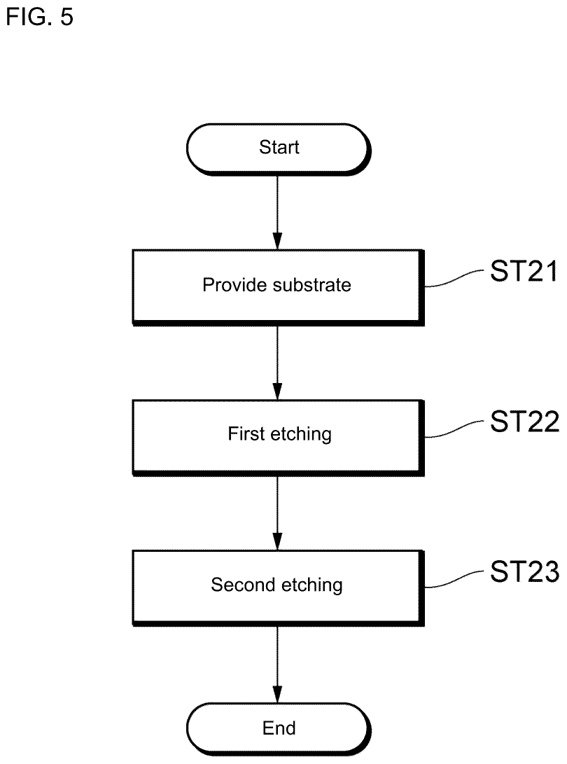

FIG. 5 is a flowchart of an exemplary processing method according to another embodiment. The processing method in this example includes step ST21 in which a substrate W1 is provided, step ST22 in which first etching is performed, and step ST23 in which second etching is performed. In this example, the first etching in step ST22 is performed under a condition different from that for the second etching in ST23.

To manufacture a semiconductor memory device such as a DRAM, for example, the temperature of the substrate W1 may be controlled to be different in steps ST22 and ST23. The processing method will be described focusing on the above. The same processing as in the flowchart shown in FIG. 2 will not be described repeatedly.

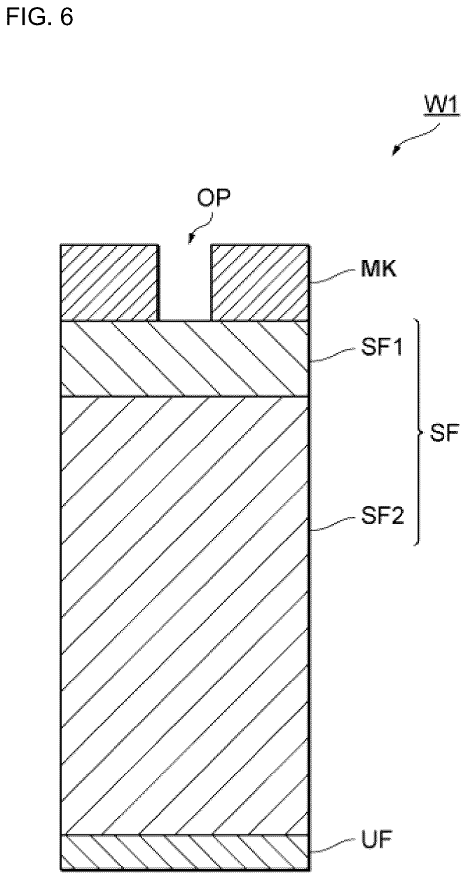

FIG. 6 is a diagram of the substrate W1 provided in step ST21, showing an example cross-sectional structure. The substrate W1 includes a silicon-containing film SF and a mask MK stacked on an underlying film UF in this order. The silicon-containing film SF includes a second silicon-containing film SF2 and a first silicon-containing film SF1 on the second silicon-containing film SF2.

The first silicon-containing film SF1 and the second silicon-containing film SF2 are different from each other. For example, the first silicon-containing film SF1 may be a silicon nitride film, whereas the second silicon-containing film SF2 may be a silicon oxide film. For example, the first silicon-containing film SF1 may be a silicon carbonitride film, whereas the second silicon-containing film SF2 may be a silicon oxide film.

In this example, the substrate W1 is placed on the substrate support 11. The first silicon-containing film SF1 is then etched with a process gas including a hydrogen fluoride gas in step ST22 in which the first etching is performed. In step ST23 in which the second etching is performed, the second silicon-containing film SF2 is etched with a process gas including a hydrogen fluoride gas. The process gases used in steps ST22 and ST23 may have the same composition or the same flow rate (partial pressure), or different compositions or different flow rates (partial pressures).

In this example, the temperature of the substrate W1 is controlled to a first temperature in step ST22, and to a second temperature different from the first temperature in step ST23. The first temperature and the second temperature may be set as appropriate for the material of the first silicon-containing film SF1 and the material of the second silicon-containing film SF2. For a first silicon-containing film SF1 being a silicon nitride film and a second silicon-containing film SF2 being a silicon oxide film, for example, the second temperature may be controlled to be lower than the first temperature. In this case, the first temperature may be controlled to −20 to 30° C. inclusive, and the second temperature to −70 to −30° C. inclusive. The difference between the first temperature and the second temperature may be 10 to 50° C. inclusive, or 20 to 40° C. inclusive. With the first temperature and the second temperature controlled in this manner, the etching rate of the silicon oxide film can be increased. The silicon oxide film may adsorb more etchant (HF species) at a lower temperature than the silicon nitride film.

The temperature of the substrate W1 may be controlled with, for example, one or more of (I) to (V) below in steps ST22 and ST23. (I) The duty ratio of the source RF signal to be provided to the upper electrode, to the lower electrode, or to both the electrodes in the plasma processing chamber 10 is changed. (II) The duty ratio of the bias signal (the bias RF signal or the bias DC signal) to be provided to the lower electrode is changed. (III) The pressure of the heat-transfer gas (e.g., He gas) between the ESC 1111 and the back surface of the substrate W is changed. (IV) The voltage (adsorption voltage) to be provided to the ESC 1111 is changed. (V) The temperature of the heat-transfer fluid flowing through the channel 1110a is changed.

As the duty ratio of each signal in (I) and (II) or the temperature of the heat-transfer fluid in (IV) increases, the heat input into the substrate W1 increases, and thus the temperature of the substrate W1 increases. As the pressure of the heat-transfer gas in (III) or the adsorption voltage in (IV) decreases, the substrate W1 dissipates less heat (or less heat is transferred to the substrate support 11), and thus the temperature of the substrate W1 increases. To increase, for example, the temperature of the substrate W1 in step ST23 to higher than in step ST22, one or more of temperature controls below may be performed in step ST23. (I) The duty ratio of the source RF signal is increased. (II) The duty ratio of the bias signal is increased. (III) The pressure of the heat-transfer gas is decreased. (IV) The adsorption voltage is decreased. (V) The temperature of the heat-transfer fluid is increased. These temperature controls may be selected based on the responsivity of each control (time taken by the temperature of the substrate W1 to change). When the temperature control (V) has lower responsivity than the other controls, the other controls (I) to (IV) may be performed (with the heat-transfer fluid maintained at a constant temperature) without the temperature control (V) being performed.

The temperature control of the substrate W1 in steps ST22 and ST23 is not limited to the above when the heat input, heat absorption, or both the heat input and the heat absorption to and from the substrate W1 can be adjusted. For example, the temperature of the substrate W1 may be controlled by increasing or decreasing the power or the voltage of the source RF signal or the bias signal. The temperature control module may be set to maintain a constant temperature to control the temperature of the substrate W1.

In this example, the first silicon-containing film SF1 and the second silicon-containing film SF2 may be etched at temperatures at which more etchant (HF species) can be adsorbed. This may improve the etching rate of the silicon-containing film SF. In contrast, the mask MK has higher etching resistance to plasma including an HF species as described above. The mask MK is thus less likely to be etched. This improves the selectivity in etching of the silicon-containing film SF to the mask MK.

In this example, the condition to be changed between steps ST22 and ST23 is not limited to the temperature of the substrate W1. To manufacture a semiconductor memory device such as a 3D-NAND, for example, the partial pressure of the gas in the process gas may be changed between steps ST23 and ST22. For a process gas including a phosphorus-containing gas, for example, the partial pressure of the phosphorus-containing gas may be changed between steps ST22 and ST23. More specifically, the partial pressure of the phosphorus-containing gas in step ST23 may be controlled to be lower than in step ST22. For a process gas including at least one metal-containing gas selected from the group consisting of a tungsten-containing gas, a titanium-containing gas, a ruthenium-containing gas, and a molybdenum-containing gas, the partial pressure of the metal-containing gas may be changed between steps ST22 and ST23. More specifically, the partial pressure of the metal-containing gas in step ST23 may be controlled to be lower than in step ST22. For a process gas including a carbon-containing gas, for example, the partial pressure of the carbon-containing gas may be changed between steps ST22 and ST23. More specifically, the partial pressure of the carbon-containing gas in step ST23 may be controlled to be lower than in step ST22. In each example, steps ST22 and ST23 may be repeated. In response to the aspect ratio of the recess RC, the condition in step ST22 may be changed to the condition in step ST23 in a stepwise or continuous manner.

The above embodiments may be modified in various manners. In one embodiment, the processing method may be performed with, in addition to the plasma processing apparatus 1 using capacitively coupled plasma, a plasma processing apparatus using any plasma source for, for example, inductively coupled plasma or microwave plasma.

In one embodiment, a declogging gas may be supplied from the gas supply unit 20 into the plasma processing space 10s during etching of the etching target film (e.g., a silicon-containing film SF, a carbon-containing film, or a metal oxide film). The declogging gas is used to reduce clogging of the opening in the mask MK. In one embodiment, the declogging gas may include at least one gas selected from the group consisting of a hydrogen gas, a nitrogen gas, an oxygen gas, a halogen gas, and a noble gas. In one embodiment, the declogging gas may react with phosphorus to generate a volatile compound. In one embodiment, the declogging gas may be at least one gas selected from the group consisting of an H₂ gas, an HBr gas, a CB₂F₂ gas, a Cl₂ gas, a BCl₃ gas, an SiCl gas, a CO gas, a CF₄ gas, a CH₄ gas, a CH₂F₂ gas, a C₃H₂F₄ gas, an N₂ gas, an NF₃ gas and an O₂ gas. An active species in plasma generated from these gases may react with phosphorus to generate a volatile compound. A phosphorus-containing deposit is thus formed on the side wall of the mask MK during etching, reducing clogging of the opening OP. In one embodiment, the declogging gas may cause less etching of the mask MK with plasma generated from the declogging gas. Examples of the declogging gas include an H₂ gas, a CF₄ gas, a CH₂F₂ gas, and a C₃H₂F₄ gas. In one embodiment, the declogging gas may be free of sulfur (S).

In one embodiment, the declogging gas may be supplied to the plasma processing space 10s as part of the process gas for etching. For example, the process gas used in step ST12, step ST22, or step ST23 may include the declogging gas. In this case, the flow rate of the declogging gas in the process gas may be constant during etching or may be increased or decreased as the etching proceeds. In one example, the process gas may include the declogging gas during one period of etching and include no declogging gas during another period of etching. In one example, the process gas may include the declogging gas with a first flow rate during one period of etching and include the declogging gas with a second flow rate lower than the first flow rate during another period of etching.

In one embodiment, the declogging gas may be supplied to the plasma processing space 10s separately from the process gas for etching. For example, an etching process with the processing method may include a first step of etching the etching target film with first plasma generated from a process gas containing phosphorus and a halogen, and a second step of removing the phosphorus-containing deposit formed on the side wall of the mask with second plasma generated from the declogging gas. In one embodiment, the first step and the second step may be repeated multiple times.

Experiment 1 for evaluating the processing method will now be described. One or more embodiments of the present disclosure is not limited to Experiment 1 described below.

In Experiment 1, the etching resistance of various films to plasma generated from a process gas including an HF gas was evaluated using the plasma processing apparatus 1. More specifically, substrates with different films to be evaluated were placed on the substrate support 11, plasma was generated from the process gas, the films were etched with the plasma, and the etching rates of the films were measured. The temperature of the substrate support 11 was set to −70° C. during the etching.

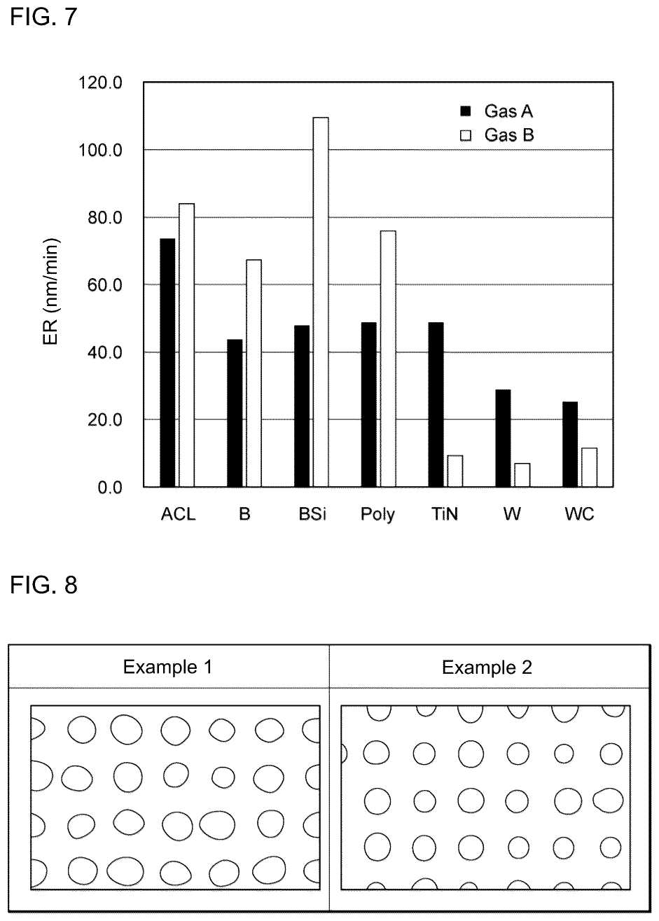

FIG. 7 is a graph showing the results of Experiment 1. In FIG. 7, the horizontal axis indicates the films evaluated in Experiment 1 with ACL for an amorphous carbon film, B for a boron film, BSi for a boron-doped silicon film. Poly for a polysilicon film, TiN for a titanium nitride film, W for a tungsten film, and WC for a tungsten carbide film. The vertical axis (ER) indicates the etching rate of the films in the unit of nm/min. Gas A represents the etching rate with plasma generated from a process gas A including an HF gas, a fluorocarbon gas, and an oxygen gas. Gas B represents the etching rate with plasma generated from a process gas B including an HF gas.

As shown in FIG. 7, for plasma generated from the process gas A, the tungsten film and the tungsten carbide film have lower etching rates and thus have higher etching resistance than the other films. For plasma generated from the process gas B, the titanium nitride film, the tungsten film, and the tungsten carbide film have lower etching rates and thus have higher etching resistance than the other films. The results show that the mask MK containing tungsten or tungsten carbide can improve selectivity in etching the silicon-containing film SF using the process gas A or B, as compared with the mask including the amorphous carbon film or other films. The results also show that the mask MK containing titanium nitride can improve selectivity in etching the silicon-containing film SF using the process gas B, as compared with the mask of amorphous carbon or other components.

### EXAMPLES

Examples of the processing method will now be described. One or more embodiments of the present disclosure is not limited to the examples described below.

### Example 1

In Example 1, a substrate W was etched using the plasma processing apparatus 1 and the procedure described with reference to FIG. 2. A tungsten silicide film with an opening pattern of holes was used as a mask MK. A film stack including a silicon oxide film and a silicon nitride film on the silicon oxide film was used as a silicon-containing film SF. In step ST12, the silicon nitride film was first etched using plasma generated from a process gas including an HF gas, a C₄F₈ gas, and an oxygen gas. The silicon oxide film was then etched using plasma generated from a process gas including an HF gas. In step ST12, the substrate support 11 was set to a temperature of −70° C.

### Example 2

The conditions in Example 2 were the same as in Example 1 except that the silicon oxide film was etched using plasma generated from a process gas including an HF gas and a phosphorus-containing gas in step ST12. The flow rate of the phosphorus-containing gas was 2 vol % of the total flow rate of the process gas.

Table 1 shows the etching results in Example 1 and Example 2. In Table 1, the selectivity to the mask indicates the selectivity of the silicon-containing film SF to the mask MK. MK ER and SF ER respectively indicate the etching rates of the mask MK and the silicon-containing film SF.

TABLE 1

| | Example 1 | Example 2 |
|---|---|---|
| Selectivity to mask | 14 | 21 |
| MK ER (nm/min) | 21 | 17 |
| SF ER (nm/min) | 296 | 359 |

As shown in Table 1, the etching rate of the mask MK is reduced, and the selectivity to the mask is improved in both Example 1 and Example 2. In Example 2, or specifically when the process gas includes the phosphorus-containing gas, the etching rate of the mask MK is further reduced, and the etching rate of the silicon-containing film SF is higher than in Example 1. The selectivity to the mask is thus further improved in Example 2 as compared with Example 1. No feature failure was observed in the opening OP or in the recess RC in Example 1 and Example 2.

FIG. 8 is a plan view of masks MK after etching, showing their features. As shown in FIG. 8, in Example 2, the openings in the mask MK after etching have higher roundness, and feature failures during etching are reduced as compared with Example 1.

### Example 3

In Example 3, a substrate W was etched using the plasma processing apparatus 1 and the procedure described with reference to FIG. 2. A tungsten silicide film with an opening pattern of holes was used as a mask MK. A film stack including silicon nitride films and silicon oxide films alternately stacked on one another was used as a silicon-containing film SF. In step ST12, etching was performed using plasma generated from a process gas including an HF gas and a phosphorus-containing gas. During the etching in step ST12, the substrate support 11 was set to a temperature of −20° C. The flow rate of the phosphorus-containing gas was 3 vol % of the total flow rate of the process gas.

In Comparative Example 1, a substrate including an amorphous carbon mask in place of the mask MK in Example 3 was etched under the same conditions as in Example 3.

Table 2 shows the etching results in Example 3 and Comparative Example 1. In Table 2, the selectivity to the mask indicates the selectivity of the silicon-containing film SF to the mask MK or the amorphous carbon mask. MK ER indicates the etching rate of the mask MK or the amorphous carbon mask. SF ER indicates the etching rate of the silicon-containing film SF. The bowing CD indicates the maximum opening width of the recess RC formed in the silicon-containing film SF by etching. The TB bias indicates the difference between the maximum opening width of the recess RC and the opening width at the top of the recess RC (the boundary with the mask MK or the amorphous carbon mask).

TABLE 2

| | Example 3 | Comparative Example 1 |
|---|---|---|
| Selectivity to mask | 39 | 10 |
| MK ER (nm/min) | 19 | 68 |
| SF ER (nm/min) | 725 | 691 |
| Bowing CD (nm) | 80 | 114 |
| TB bias (nm) | 9 | 16 |

As shown in Table 2, in Example 3, the silicon-containing film SF has a high etching rate, whereas the mask MK has a relatively low etching rate. The selectivity to the mask is notably high. In Comparative Example 1, although the silicon-containing film SF has substantially the same etching rate as in Example 3, the amorphous carbon mask also has a high etching rate. The selectivity to the mask is about one quarter of that in Example 3. In addition, both the bowing CD and the TB bias are relatively low in Example 3, indicating less bowing. In contrast, both the bowing CD and the TB bias are higher in Comparative Example 1, indicating failure to reduce bowing.

### Example 4

In Example 4, a substrate W was etched using the plasma processing apparatus 1 and the procedure described with reference to FIG. 2. A tungsten silicide film with an opening pattern of holes was used as a mask MK. A film stack including silicon nitride films and silicon oxide films alternately stacked on one another was used as a silicon-containing film SF. In step ST12, etching was performed using plasma generated from a process gas including an HF gas and a phosphorus-containing gas. The temperature of the substrate support 11 was set to −50° C. during the etching.

### Examples 5 to 11

In Examples 5 to 11, a substrate W with the same structure as in Example 4 was etched under the same conditions as in Example 4, except that the gases shown in Table 3 were added to the respective process gases.

Table 3 shows the etching results in Examples 4 to 11. In Table 3, the additive gas indicates the gas added to the respective process gas. The selectivity to the mask indicates the selectivity of the silicon-containing film SF to the mask MK. The necking CD indicates the minimum opening width of the opening OP in the mask MK.

TABLE 3

| | Additive gas | Selectivity to mask | Necking CD (nm) |
|---|---|---|---|
| Example 4 | — | 26 | 37 |
| Example 5 | H₂ gas | 23 | 44 |
| Example 6 | CH₄ gas | 23 | 45 |
| Example 7 | C₃H₂F₄ gas | 26 | 51 |
| Example 8 | CF₄ gas | 18 | 44 |
| Example 9 | NF₃ gas | 11 | 73 |
| Example 10 | O₂ gas | 17 | 51 |
| Example 11 | COS gas | 16 | 22 |

As shown in Table 3, the selectivity to the mask is improved in all the examples. An H₂ gas, a CH₄ gas, a C₃H₂F₄ gas, a CF₄ gas, an NF₃ gas, or an O₂ gas was added as an additive gas to the process gas in Examples 5 to 10. In Examples 5 to 10, the necking CD is greater than in Example 4, indicating less clogging of the opening in the mask MK. The selectivity to the mask in Examples 5 to 7, in which an H₂ gas, a CH₄ gas, and a C₃H₂F₄ gas was added as the process gas, is comparable to that in Example 4. A COS gas was added to the process gas in Example 11. In Example 11, the selectivity to the mask and the necking CD are smaller than in Example 4.

### Example 12

In Example 12, a substrate W was etched using the plasma processing apparatus 1 and the procedure described with reference to FIG. 2. A ruthenium film with an opening pattern of holes was used as a mask MK. A silicon oxide film was used as a silicon-containing film SF. In step ST12, etching was performed for 30 seconds using plasma generated from a process gas including an HF gas. The temperature of the substrate support 11 was set to −70° C. during the etching.

### Example 13

In Example 13, a substrate W with the same structure as in Example 12 was etched under the same conditions as in Example 12, except that the process gas further included a phosphorus-containing gas.

Table 4 shows the etching results in Examples 12 and 13. The selectivity to the mask indicates the selectivity of the silicon-containing film SF to the mask MK. MK ER indicates the etching rate of the mask MK. SF ER indicates the etching rate of the silicon-containing film SF. The bowing CD indicates the maximum opening width of the recess RC formed in the silicon-containing film SF by etching.

TABLE 4

| | Example 12 | Example 13 |
|---|---|---|
| Selectivity to mask | 63 | 199 |
| MK ER (nm/min) | 14 | 8 |
| SF ER (nm/min) | 884 | 1594 |
| Bowing CD (nm) | 58 | 56 |

As shown in Table 4, in Example 12, the mask MK (ruthenium film) remained substantially unetched during etching of the silicon-containing film SF. The selectivity to the mask is thus sufficiently high. The HF species in the plasma accelerated etching of the silicon-containing film SF. However, the mask MK including the ruthenium film has high resistance to the HF species. The mask MK thus seemingly remains substantially unetched. The results in Example 13 show this trend more notably than in Example 12. More specifically, the silicon-containing film SF in Example 13 has a still higher etching rate than the silicon-containing film SF in Example 12, whereas the mask MK in Example 13 has a still lower etching rate than the mask MK in Example 12. The selectivity to the mask is thus notably high. The bowing CD is also improved in Example 13 as compared with Example 12.

The embodiments of the present disclosure further include the aspects described below.

### Appendix 1

An etching method in a chamber of a plasma processing apparatus, the method comprising:
(a) providing, in the chamber, a substrate including an etching target film and a mask on the etching target film, the mask comprising at least one metal selected from the group consisting of tungsten, molybdenum, ruthenium, titanium, indium, gallium, and zinc; and
(b) etching the etching target film using plasma generated from a process gas including a hydrogen fluoride gas.

### Appendix 2

The etching method according to appendix 1, wherein
the mask comprises a carbide or a silicide of the at least one metal.

### Appendix 3

The etching method according to appendix 1, wherein
the mask comprises at least one selected from the group consisting of Ru, WSi, TIN, Mo, and InGaZnO.

### Appendix 4

The etching method according to appendix 3, wherein
the mask further comprises at least one selected from the group consisting of silicon, carbon, and nitrogen.

### Appendix 5

The etching method according to any one of appendixes 1 to 4, wherein
the process gas further includes a phosphorus-containing gas.

### Appendix 6

The etching method according to appendix 5, wherein
the phosphorus-containing gas includes a phosphorus halide gas.

### Appendix 7

The etching method according to appendix 5 or appendix 6, wherein
the phosphorus-containing gas comprises at least one of fluorine or chlorine.

### Appendix 8

The etching method according to any one of appendixes 1 to 7, wherein
the process gas includes the hydrogen fluoride gas with a highest flow rate of non-inert components of the process gas.

### Appendix 9

The etching method according to any one of appendixes 1 to 8, wherein
the process gas further includes at least one gas selected from the group consisting of a tungsten-containing gas, a titanium-containing gas, and a molybdenum-containing gas.

### Appendix 10

The etching method according to any one of appendixes 1 to 8, wherein
the process gas further includes oxygen-containing gas.

### Appendix 11

The etching method according to any one of appendixes 1 to 10, wherein
(b) includes setting a temperature of a substrate support supporting the substrate to 0° C. or lower.

### Appendix 12

The etching method according to any one of appendixes 1 to 11, wherein
the etching target film includes at least one selected from the group consisting of a silicon oxide film, a silicon nitride film, a polysilicon film, and a film stack including at least two of the silicon oxide film, the silicon nitride film, or the polysilicon film.

### Appendix 13

The etching method according to any one of appendixes 1 to 11, wherein
the etching target film is a silicon-containing film, a carbon-containing film, or a metal oxide film.

### Appendix 14

The etching method according to any one of appendixes 1 to 11, wherein
the etching target film is a film stack including a silicon oxide film and a silicon nitride film, and (b) includes (b1) etching the silicon oxide film and (b2) etching the silicon nitride film, and
(b) includes controlling a temperature of the substrate to be higher in (b2) than in (b1).

### Appendix 15

The etching method according to appendix 14, wherein
the controlling the temperature includes at least one selected from the group consisting of
(I) controlling a duty ratio of a source radio frequency signal to be provided to the chamber to be greater in (b2) than in (b1),
(II) controlling a duty ratio of a bias signal to be provided to a substrate support supporting the substrate to be greater in (b2) than in (b1).
(III) controlling a pressure of a heat-transfer gas to be supplied between the substrate and the substrate support to be lower in (b2) than in (b1).
(IV) controlling a voltage to be provided to an electrostatic chuck in the substrate support to be lower in (b2) than in (b1), and
(V) controlling a temperature of a heat-transfer fluid to be supplied to a channel in the substrate support to be higher in (b2) than in (b1).

### Appendix 16

The etching method according to appendix 15, wherein
the heat-transfer fluid has a same temperature in (b1) and (b2), and the controlling the temperature includes at least one selected from the group consisting of (I) to (IV).

### Appendix 17

An etching method in a chamber of a plasma processing apparatus, the method comprising:
(a) providing, in the chamber, a substrate including an etching target film and a mask on the etching target film, the mask comprising at least one selected from the group consisting of tungsten, molybdenum, ruthenium, titanium, indium, gallium, and zinc; and
(b) etching the etching target film using plasma including a hydrogen fluoride species.

### Appendix 18

The etching method according to appendix 17, wherein
the hydrogen fluoride species is generated from at least one of a hydrogen fluoride gas or a hydrofluorocarbon gas.

### Appendix 19

The etching method according to appendix 17, wherein
the hydrogen fluoride species is generated from a hydrofluorocarbon gas having at least two carbon atoms.

### Appendix 20

The etching method according to appendix 17, wherein
the hydrogen fluoride species is generated from a mixture gas including a hydrogen source and a fluorine source.

### Appendix 21

A plasma processing system, comprising:
a plasma processing apparatus including a chamber; and
a controller, the controller being configured to perform control to cause operations including
(a) providing, in the chamber, a substrate including an etching target film and a mask on the etching target film, the mask comprising at least one metal selected from the group consisting of tungsten, molybdenum, ruthenium, titanium, indium, gallium, and zinc, and
(b) etching the etching target film using plasma generated from a process gas including a hydrogen fluoride gas.

### Appendix 22

The etching method according to any one of appendixes 1 to 20, wherein
the mask comprises tungsten.

### Appendix 23

The etching method according to any one of appendixes 1 to 20, wherein
the etching target film is a silicon-containing film.

### Appendix 24

The etching method according to appendix 23, wherein
the silicon-containing film is a film stack including a silicon oxide film and a silicon nitride film.

### Appendix 25

A device manufacturing method in a chamber of a plasma processing apparatus, the method comprising:
(a) providing, in the chamber, a substrate including an etching target film and a mask on the etching target film, the mask comprising at least one metal selected from the group consisting of tungsten, molybdenum, ruthenium, titanium, indium, gallium, and zinc; and
(b) etching the etching target film using plasma generated from a process gas including a hydrogen fluoride gas.

### Appendix 26

A program executable by a computer in a plasma processing system, the plasma processing system including a plasma processing apparatus including a chamber, and a controller, the program causing the computer to control operations comprising:
(a) providing, in the chamber, a substrate including an etching target film and a mask on the etching target film, the mask comprising at least one metal selected from the group consisting of tungsten, molybdenum, ruthenium, titanium, indium, gallium, and zinc; and
(b) etching the etching target film using plasma generated from a process gas including a hydrogen fluoride gas.

### Appendix 27

A storage medium storing the program according to appendix 26.

### Appendix 28

An etching method in a chamber of a plasma processing apparatus, the method comprising:
(a) providing, in the chamber, a substrate including an etching target film and a mask on the etching target film, the mask comprising at least one metal selected from the group consisting of tungsten, molybdenum, ruthenium, titanium, indium, gallium, and zinc; and
(b) etching the etching target film with plasma supplied to the substrate, the plasma being generated from a process gas including a first gas and a second gas, the first gas comprising phosphorus and a halogen, the second gas being reactive with the phosphorus to generate a volatile compound.

### Appendix 29

An etching method in a chamber of a plasma processing apparatus, the method comprising:
(a) providing, in the chamber, a substrate including an etching target film and a mask on the etching target film, the mask including, on the etching target film, a side wall defining an opening, the mask comprising at least one metal selected from the group consisting of tungsten, molybdenum, ruthenium, titanium, indium, gallium, and zinc;
(b) etching the etching target film with first plasma supplied to the substrate, the first plasm being generated from a first gas comprising phosphorus and a halogen, the mask receiving a phosphorus-containing deposit forming on the side wall; and
(c) removing the phosphorus-containing deposit with second plasma supplied to the substrate, the second plasma being generated from a second gas including at least one gas selected from the group consisting of a hydrogen gas, a nitrogen gas, an oxygen gas, a halogen gas, and a noble gas.

### Appendix 30

The etching method according to appendix 29, wherein
(b) and (c) are performed alternately.

### Appendix 31

The etching method according to any one of appendixes 28 to 30, wherein
the first gas includes a hydrogen fluoride gas.

### Appendix 32

The etching method according to any one of appendixes 28 to 30, wherein
the second gas is a hydrogen-containing gas.

### Appendix 33

The etching method according to appendix 32, wherein
the hydrogen-containing gas includes at least one gas selected from the group consisting of an H₂ gas, a CH₄ gas, a CH₂F₂ gas, and a C₃H₂F₄ gas.

### Appendix 34

The etching method according to any one of appendixes 28 to 30, wherein the second gas is a nitrogen-containing gas.

### Appendix 35

The etching method according to appendix 34, wherein
the nitrogen-containing gas is at least one of an N₂ gas or an NF₃ gas.

### Appendix 36

The etching method according to any one of appendixes 28 to 30, wherein
the second gas is free of sulfur.

### Appendix 37

An etching method in a chamber of a plasma processing apparatus, the method comprising:
(a) providing, in the chamber, a substrate including an etch stop film, an etching target film on the etch stop film, and a mask on the etching target film, the etch stop film comprising at least one metal selected from the group consisting of tungsten, molybdenum, ruthenium, titanium, indium, gallium, and zinc; and
(b) etching the etching target film using plasma generated from a process gas including a hydrogen fluoride gas.

### Appendix 38

The etching method according to appendix 37, wherein
the etch stop film comprises at least one selected from the group consisting of Ru, WSi, TiN, Mo, and InGaZnO.

The above embodiments are mere examples described for illustrative purposes and are not intended to limit the scope of the present disclosure. The embodiments may be modified in various ways without departing from the spirit and scope of the present disclosure. For example, one or more components in one embodiment may be added to the structure according to another embodiment. One or more components in one embodiment may be replaced with the corresponding one or more components in another embodiment.

### REFERENCE SIGNS LIST

1 Plasma processing apparatus
2 Controller
10 Plasma processing chamber
10s Plasma processing space
11 Substrate support
13 Shower head
20 Gas supply unit
31a First RF generator
31b Second RF generator
32a First DC generator
SF Silicon-containing film
MK Mask
OP Opening
RC Recess
UF Underlying film
W, W1 Substrate

What is claimed is:

1. An etching method in a chamber of a plasma processing apparatus, the method comprising:
(a) providing, in the chamber, a substrate including an etching target film and a mask on the etching target film, the mask comprising at least one metal selected from the group consisting of tungsten, molybdenum, ruthenium, titanium, indium, gallium, and zinc; and
(b) etching the etching target film using plasma generated from a process gas including a hydrogen fluoride gas.

2. The etching method according to claim 1, wherein
the mask comprises a carbide or a silicide of the at least one metal.

3. The etching method according to claim 1, wherein
the mask comprises at least one selected from the group consisting of Ru, WSi, TiN, Mo, and InGaZnO.

4. The etching method according to claim 3, wherein
the mask further comprises at least one selected from the group consisting of silicon, carbon, and nitrogen.

5. The etching method according to claim 1, wherein
the process gas further includes a phosphorus-containing gas.

6. The etching method according to claim 5, wherein
the phosphorus-containing gas includes a phosphorus halide gas.

7. The etching method according to claim 5, wherein
the phosphorus-containing gas comprises at least one of fluorine or chlorine.

8. The etching method according to claim 1, wherein
the process gas includes the hydrogen fluoride gas with a highest flow rate of non-inert components of the process gas.

9. The etching method according to claim 1, wherein
the process gas further includes at least one gas selected from the group consisting of a tungsten-containing gas, a titanium-containing gas, and a molybdenum-containing gas.

10. The etching method according to claim 5, wherein
the process gas further includes oxygen-containing gas.

11. The etching method according to claim 1, wherein
(b) includes setting a temperature of a substrate support supporting the substrate to 0° C. or lower.

12. The etching method according to claim 1, wherein
the etching target film includes at least one selected from the group consisting of a silicon oxide film, a silicon nitride film, a polysilicon film, and a film stack including at least two of the silicon oxide film, the silicon nitride film, or the polysilicon film.

13. The etching method according to claim 1, wherein
the etching target film is a silicon-containing film, a carbon-containing film, or a metal oxide film.

14. The etching method according to claim 1, wherein
the etching target film is a film stack including a silicon oxide film and a silicon nitride film, and (b) includes (b1) etching the silicon oxide film and (b2) etching the silicon nitride film, and
(b) includes controlling a temperature of the substrate to be higher in (b2) than in (b1).

15. The etching method according to claim 14, wherein
the controlling the temperature includes at least one selected from the group consisting of
(I) controlling a duty ratio of a source radio frequency signal to be provided to the chamber to be greater in (b2) than in (b1),
(II) controlling a duty ratio of a bias signal to be provided to a substrate support supporting the substrate to be greater in (b2) than in (b1),
(III) controlling a pressure of a heat-transfer gas to be supplied between the substrate and the substrate support to be lower in (b2) than in (b1),
(IV) controlling a voltage to be provided to an electrostatic chuck in the substrate support to be lower in (b2) than in (b1), and
(V) controlling a temperature of a heat-transfer fluid to be supplied to a channel in the substrate support to be higher in (b2) than in (b1).

16. The etching method according to claim 15, wherein
the heat-transfer fluid has a same temperature in (b1) and (b2), and the controlling the temperature includes at least one selected from the group consisting of (I) to (IV).

17. An etching method in a chamber of a plasma processing apparatus, the method comprising:
(a) providing, in the chamber, a substrate including an etching target film and a mask on the etching target film, the mask comprising at least one selected from the group consisting of tungsten, molybdenum, ruthenium, titanium, indium, gallium, and zinc; and
(b) etching the etching target film using plasma including a hydrogen fluoride species.

18. The etching method according to claim 17, wherein
the hydrogen fluoride species is generated from at least one of a hydrogen fluoride gas or a hydrofluorocarbon gas.

19. The etching method according to claim 17, wherein
the hydrogen fluoride species is generated from a hydrofluorocarbon gas having at least two carbon atoms.

20. The etching method according to claim 17, wherein
the hydrogen fluoride species is generated from a mixture gas including a hydrogen source and a fluorine source.

21. A plasma processing system, comprising:
a plasma processing apparatus including a chamber; and
a controller, the controller being configured to perform control to cause operations including
(a) providing, in the chamber, a substrate including an etching target film and a mask on the etching target film, the mask comprising at least one metal selected from the group consisting of tungsten, molybdenum, ruthenium, titanium, indium, gallium, and zinc, and
(b) etching the etching target film using plasma generated from a process gas including a hydrogen fluoride gas.
